(19) United States
(12) Patent Application Publication
(10) Pub. No.: US 2010/0141243 A1
(43) Pub. Date: Jun. 10, 2010

(54) RESISTIVE POSITION-SENSING SYSTEM INCLUDING A STACKED SWITCH ARRAY, AND COMPONENTS THEREOF

(76) Inventors: Andrew T. Divicino, Durham, CT (US); Philip J. Mader, Kensington, CT (US)

Correspondence Address: David Fink, 7519 Apache Plume, Houston, TX, 77071, US

(21) Appl. No.: 12/450,392

(22) PCT Filed: Mar. 31, 2008
(86) PCT No.: PCT/US2008/004203

§ 371 Date: Dec. 14, 2009

Related U.S. Application Data
(60) Provisional application No. 61/009,521, filed on Dec. 28, 2007.
(60) Provisional application No. 60/921,617, filed on Apr. 2, 2007.

(51) Int. Cl. G01R 33/09

(52) U.S. Cl. 324/207.21

(57) ABSTRACT

The position-monitoring system consists of cooperating arrays in the form of an assembly of switch/resistance element units, serving as a sensor component, and an assembly of magnet units, serving as an actuator component, each switch unit including a switching device that is magnetically operated for connecting or disconnecting an associated resistance element to or from a common circuit through the switch stack. The resultant change of resistance in the common circuit is detected and utilized for determining the position of a movable member, to which one of the stacks is operatively attached, relative to another member to which the other stack is attached.

### CROSS-REFERENCE TO RELATED APPLICATIONS

This application claims the benefit of U.S. Provisional Patent Application No. 60/921,617, filed Apr. 2, 2007, and of U.S. Provisional Patent Application No. 61/009,521, filed Dec. 28, 2007. The entire specifications of both of the foregoing provisional applications are incorporated hereinto by reference thereto.

### BACKGROUND OF THE INVENTION

There are numerous applications in which the position of a movable member, relative to adjacent structure, is to be determined. The determination is desirably (or, in certain instances, necessarily) made by generating and measuring a position-dependent electrical signal.

One application for such a system that has received considerable attention in the art concerns the positioning of a movable sash in a fume hood. For example, U.S. Pat. No. 4,706,553 describes a controller system in which sash position is monitored by a transducer to provide a signal that is indicative of the area of a fume hood opening. U.S. Pat. No. 4,893,551 discloses an apparatus for sensing the extent to which a fume hood opening is uncovered by the sashes, utilizing detectors to sense radiation from an optical or magnetic emitter. And U.S. Pat. No. 6,994,619 provides a sash-sensing system for controlling the flow of air into a fume hood, utilizing an optical sensing device and a reflective tape. Apparatus of kind described is believed to be common, and commercially available.

Nevertheless, the need remains for a position-sensing system in which the physical extent of its operative components is readily varied and selected and, once selected, is readily embodied in physical form, which system is of incomplex and inexpensive construction, is facile to assemble and install, and affords a wide scope and high degree of flexibility in its applications.

### SUMMARY OF THE INVENTION

The foregoing objects are achieved, in accordance with the present invention, usually by the provision of a system consisting basically of two assemblies (stacks or arrays), each being constructed from a multiplicity of units, or segments, which are normally of modular form and are readily assembled with one another to produce linear or curvilinear arrays of virtually any practical length or extent. The units of one of the assemblies (sensor means, or “switch array”) contains an electrical resistance element and associated switching means (referred to for convenience generally as a “switch”), which switch can be operated so as to vary the electrical resistance in a common circuit that is established through the array. The other assembly (actuator means) usually consists of a multiplicity of adjacent actuating units, which are attached to one another so that they also form an array. The switch will preferably be operated magnetically, and the actuating units will comprise magnets, forming a “magnet array.”

Depending upon the extent of effective overlap of the two assemblies, any number of the switches present will be operated, in sequence, by the actuating effect (magnetic flux) to which they are subjected. The resistance of the associated resistance element will thereby be either removed from (by short circuiting, to short it out), or impressed upon, the circuit carried by the switch array. By measuring the total resistance in the circuit, the position of a movable member, on which one of the two arrays is mounted, can readily be determined (provided of course that the resistance elements all have the same ohmic value, or that the necessary correlation can be made otherwise). The output of a current applied to the switch stack, as so modified by the resistance variation, can be utilized by suitable control means for adjusting the position of the movable member or for other purposes, as will be evident to those skilled in the art.

A highly desirable feature of the system of the invention resides in the utilization not only of a single form of housing for both the switch/resistor units and also the magnet units, but also in the use of a single form of housing component that can be paired for constructing each unit.

Alarm systems are of course well known in which a reed switch or the like, and an actuating magnet, are separately mounted on a window or door sash and an adjacent frame part for initiating an alarm, or performing another function, when a circuit including the switch is broken by opening the door or window; such systems may include a programmable logic controller. The system of the present invention, in contrast, comprises multiple switches that are stacked together as an array and that function to generate a signal that is proportionate to the length of overlap with the units of a cooperating magnet stack.

Assemblies comprising the present system are readily retrofit to existing members and structures without need for prior measurement or for additional manufacture to conform them to the members and structures; they may of course also be supplied as an OEM feature. Specific applications for the system include the control of a mechanical air supply system, adapted as to account, for example, for the effects of a partially opened fenestration (which may be accomplished by enabling a length or area calculation), as in a fume hood or a common doorway or window; the determination and control of the area of a “air curtain” to optimize mechanical fan energy; and the determination and control of the level of liquid in a tank, the position of a flag on a pole, etc. Curvilinear arrays can, for example, be used to determine the position of a rotary valve, and myriad other applications will be evident, from the present description, to those skilled in the art.

More specifically, certain objects of the invention are provided by the provision of a position-sensing system comprised of: a switch array comprising an assembly of a multiplicity of separate switch units arranged seriatim, each of the switch units including an electrical circuit section, an electrical resistance element, and a switch that is operable for movement between two positions to effectively connect the resistance element to the electrical circuit section in one of the positions and to effectively disconnect the resistance element from the circuit section in the other of the positions, the circuit section having a plurality of terminals for operative electrical connection to a circuit section of a proximate one of the switch units so as to form common circuitry therewith; an actuator (magnet) array, of similar form to the switch array, comprising an assembly of a multiplicity of separate magnet units arranged seriatim, each of the magnet units including a magnet element that is effective for operating the switch of each of the switch units of the switch array when positioned proximate thereto; and means for electrically interconnecting free terminals of one of the switch units of the switch array for establishing electrical continuity therebetween.

In certain preferred embodiments the switch units of the switch array are substantially identical to one another, and the magnet units of the magnet array are also substantially identical to one another. Each of the switch units and each of the magnet units may comprise a housing defining at least one chamber therewithin, with the chambers of the switch units containing the resistance elements and the switches, and the chambers of the magnet units containing the magnet elements. All of the housings, comprising both the switch units and also the magnet units, will most desirably be substantially identical, and each of the housings will advantageously comprise a pair of substantially identical components fabricated from an electrically insulating material and joined to one another face-to-face in an end-to-end inverted relative orientation.

The housing of each switch unit will have opposite ends, one of which will usually comprise at least one projecting element and the other of which defines at least one socket, the at least one projecting element and the at least one socket being dimensioned and configured for mated interfitting to enable assembly of adjacent switch units with the at least one projecting element of one switch unit received within the at least one socket of the adjacent switch unit. In such embodiments, two terminals of the electrical circuit section are effectively present on the at least one projecting element of the switch unit housing, and two terminals of the electrical circuit section are effectively present within the socket of the switch unit housing so that, with the at least one projecting element of the one unit and the at least one socket of the adjacent unit matingly interfit, each of the terminals on the at least one projecting element of the one switch unit electrically connects to a corresponding one of the terminals within the at least one socket of the adjacent switch unit.

Generally, one end of each such switch unit will comprise two substantially parallel projecting elements, providing the at least one projecting element, with each of the parallel projecting elements having one of the terminals of the electrical circuit section effectively present thereon; the other end of the switch unit will, in such embodiments, define two substantially parallel sockets, each having one of the terminals effectively present therewithin and the parallel sockets being dimensioned and configured to matingly interfit with the parallel projecting elements of the adjacent switch unit, with the corresponding terminals thereof electrically interconnected. Normally, the projecting elements and the sockets of the housings will be formed for retentive interengagement when interfit with one another.

In other embodiments, at least one of the opposite ends of a plurality of the housings will comprise at least one projecting element, and the system will additionally include a plurality of coupling members. Each of the coupling members will have opposite ends in each of which is defined at least one socket, the at least one projecting element of the plurality of housings and the at least one socket of the plurality of coupling members being dimensioned and configured for mated interfitting to enable assembly of two of the switch units or two of the magnet units with one of the coupling members interposed therebetween with the projecting elements of the two switch units or the two magnet units received within the socket in each of the opposite ends of the coupling member. The coupling members may have electrical conductor means therein for establishing operative electrical connection between the circuit sections of two of the switch units assembled with the interposed of the coupling member. When the housings are magnet unit housings, the coupling members will usually be devoid of operative electrical interconnection means. Alternatively, the housings can define sockets in both of their opposite ends, with the coupling members comprising the interfitting projecting elements.

The means for electrically connecting the free terminals of one switch unit of the switch array will normally be a shunt unit comprising a housing containing an electrical conductor having terminals for electrical connection to the free terminals of the one switch unit. Such a shunt unit housing will be assembled with an endmost switch unit of the switch array, and the conductor terminals of the shunt unit will be electrically connected to free terminals of the endmost switch unit to establish electrical continuity therebetween.

In most instances, the resistance elements of all of the switch units will have the same ohmic value. The switch of the each switch unit may desirably be a reed switch, and the magnet element of the each magnet unit will desirably be a permanent magnet. An electric circuit board, contained within the chamber of the housing of each of the switch units, will advantageously provide the electrical circuit section, the electrical resistance element, and the switch thereof. The resistance element of each of the switch units may be normally effectively connected in the circuit section thereof, with the switch in the one position, and the switch will be effective, in the other position thereof, to short circuit the resistance element.

The switch array and the magnet array will, in many cases, be of rectilinear form. Alternatively, they may be of curvilinear form. In the latter case, the arrays may comprise circular sections and have the same effective radius, or the effective radius of one of the arrays may be smaller than that of the other, so as to enable the arrays to be concentrically disposed relative to one another. Each of the switch units and each of the magnet units will usually have means thereon for affixing it to a support member.

Other objects of the invention are attained by the provision of a position-sensing assembly including first and second members disposed for relative movement adjacent to one another; a position-sensing system, as herein described; and means for mounting the switch array on the first member and for mounting the magnet array on the second member. The arrays are so positioned that, upon relative adjacent movement of the members, the arrays move past one another along a path having at least a section within which the magnet elements of a variable plurality of the magnet units effectively overlap the switches of a variable plurality of the switch units, so as to magnetically effect operation of the switches between the two positions thereof. Such an assembly will normally additionally include means for measuring the electrical resistance of the common circuitry formed through the switch array and for thereby enabling the determination of a position-dependent factor based upon the relative positions of the first and second members.

The first and second members of the assembly may be supported for relative movement in parallel planes, in which case a first member will generally comprise stationary structure disposed substantially in or on a first plane and a second member will be movable in an adjacent plane; the second member will typically comprise at least one panel. The first and second members may alternatively be supported for relative rotational movement.

Still other objects of the invention are attained by the provision of a module constructed for end-to-end, mutually adjacent assembly with like modules, arranged seriatim, for forming an array adapted for use in a position-sensing system. Such a module will comprise a housing that defines at least one chamber therewithin, dimensioned and configured for containing at least one of a switch and resistance element combination and a magnet element, and having other features herein described. Internal structure of each of the housing components will desirably define a compound recess for forming, in cooperation with a another such housing component so joined, a chamber configured to separately and selectively receive and seat a magnet element and an electric circuit board. More specifically, the internal structure will desirably define a first, generally rectangular recess portion for receiving and seating a circuit board, and a second, generally rectangular recess portion, narrower than the first recess portion and disposed in a traversing, centralized position relative thereto, for receiving and seating a magnet element.

### BRIEF DESCRIPTION OF THE DRAWINGS

FIG. 1 is a perspective view of a modular unit utilized in the system of the invention and containing either an electric circuit board or a magnet element;

FIG. 2 is a perspective view showing a housing component from which the unit depicted in FIG. 1 is constructed, including an electric circuit board shown in phantom line;

FIG. 3 is a side elevation view of the housing component depicted in FIG. 2;

FIG. 4 is a plan view of the housing component of FIG. 2;

FIG. 5 is an exploded end elevational view of the base and cover components comprising the unit of FIG. 1, disposed in face-to-face relationship prior to assembly with one another;

FIG. 6 is a perspective view similar to FIG. 2, showing, in phantom line, a permanent magnet element seated in the housing component;

FIGS. 7a and 7b are, respectively, a plan view and a side elevational view of the electric circuit board employed in the unit shown in FIGS. 2 and 4;

FIG. 8 is a plan view of a female end cap utilized in the assemblies comprising the system of the invention;

FIGS. 9 and 10 are, respectively, perspective and plan views showing one component of the female end cap, specifically adapted for use in a switch stack comprising the system of the invention;

FIG. 11 is a plan view of a male end cap employed in the assemblies comprising the system of the invention;

FIGS. 12 and 13 are, respectively, perspective and plan views of one component of the male end cap, specifically adapted for use as a shunt component in a switch stack comprising the system of the invention;

FIG. 14 is a plan view depicting a rectilinear switch stack embodying the system of the invention, housing components being removed to expose internal features;

FIG. 15 is a view similar to FIG. 14 depicting a magnet stack assembly;

FIG. 16 is a schematic diagram showing the electrical circuitry of the switch stack;

FIGS. 17a and 17b are, respectively, illustrations of cooperating assemblies of the invention, mounted separately upon each member of a set of relatively movable, adjacent members, FIG. 17a showing the assemblies in a non-overlapped and magnetically non-interactive relative position, and FIG. 17b showing the assemblies in an overlapped relationship such that one of the magnet units operates the reed switch of one of the switch/resistor units;

FIGS. 18a and 18b are illustrations of a position sensor system embodying the invention installed on a sliding door arrangement, FIG. 18b showing fragmentarily the top portion of the inside of the sliding door;

FIG. 19 is an illustration showing the position sensor system of the invention installed for detecting liquid levels;

FIGS. 20a and 20b are front and side elevational views showing the system of the invention installed for determining the height position of an overhead garage door, FIG. 20b showing an edge of the door;

FIG. 21b is a plan view of a modular unit and a coupling component constructed for assembly therewith; FIG. 21c is a plan view of one of the pairs of housing components from which the unit and component are constructed; and FIG. 21a is a fragmentary plan view of a system comprised a seriatim array of a multiplicity of the modular units and coupling components assembled with one another;

FIG. 22 is a view similar to FIG. 7a, showing an alternate circuit board suitable for use in the unit of FIGS. 2 and 4;

FIGS. 23a and 23b are, respectively, plan views of an angled modular unit, and one of the pairs of housing components from which the unit is constructed, constituting one alternative to the form of the unit shown, for example, in FIGS. 1-4;

FIGS. 24a and 24b are, respectively, plan views of an arcuate modular unit, and one of the pairs of housing components from which it is constructed, constituting another alternative to the form of the unit shown, for example, in FIGS. 1-4;

FIG. 25a is a plan view of a circular array of housing components of units of the form shown in FIGS. 24a and 24b; FIG. 25b is a schematic top (or front) view of cooperating arrays that have the same diameter, assembled from units of the form shown in FIG. 25a, and arranged in a proximate, operatively adjacent relative position; and FIG. 25c is a view similar to 25a but showing the housing components in an exploded relationship;

FIG. 26 is a view similar to FIG. 25a, wherein the switch and magnet arrays are both of semicircular form;

FIG. 27 is a schematic diagram showing arrays of switch units and actuating units having different radii and arranged concentrically on components of a valve; and

FIG. 28 is a schematic diagram showing a sensor array and an actuating component having different radii and arranged concentrically, and being of greater curvilinear extent than the arrays of FIG. 27.

### DETAILED DESCRIPTION OF THE ILLUSTRATED EMBODIMENTS

As seen in FIG. 1, the housing comprising each modular unit of the system illustrated consists of a base component and a cover component, fabricated from an electrically insulating synthetic resinous material and generally designated, respectively, by the numerals 10 and 10′. It is to be appreciated that, despite the different designations, the base and cover components are identical to one another.

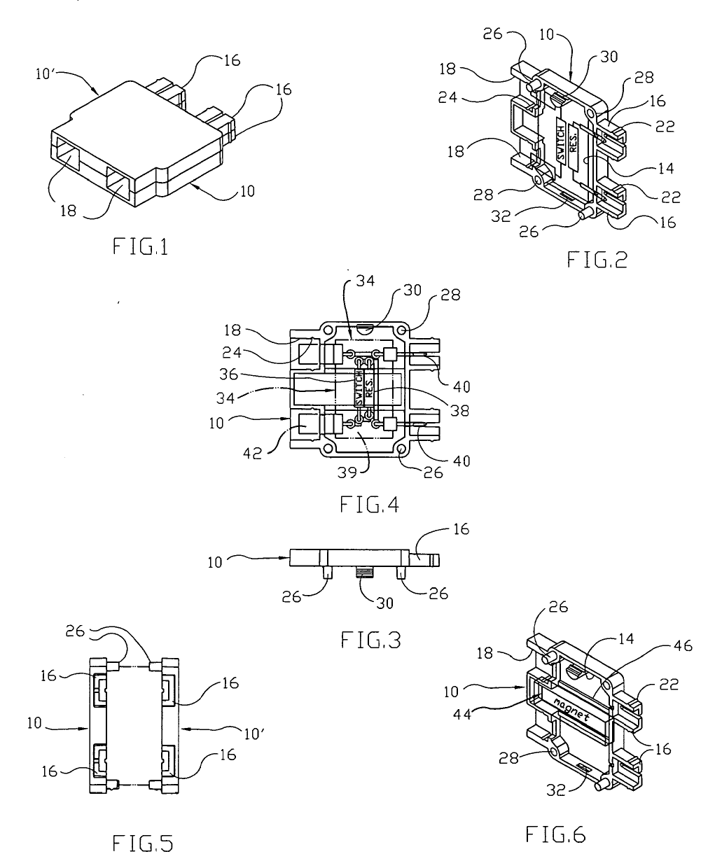

The component depicted in FIGS. 2-4 is arbitrarily referred to as the base 10 of the housing, and is seen to include a body 12 within which is defined a recess 14. A pair of parallel male connecting elements 16 project from one end of the component 10, and a corresponding pair of female connecting elements, comprising parallel, open-ended channel sections 18, are defined by the housing structure at the opposite end of the component.

It will be appreciated that complete male connecting projections are formed when the base and cover components 10, 10′ are assembled in face-to-face relationship, as indicated in FIG. 5, and that a pair of inwardly expending sockets, providing female connecting receptacles, are formed simultaneously. The male connecting elements 16 are provided with rib elements 22 and the structure defining each female receptacle is formed with corresponding grooves 24 disposed within the channel sections 18. Needless to say, these features enable multiple units to be snap-fit together directly, seriatim and in endwise (end-to-end) relationship to form a linear array, by inserting the male connecting projections into the female receptacles.

It can also be seen that each component 10, 10′ is formed with a pair of posts 26, disposed on the diagonal in cater-corner relationship to one another, and with a pair of holes 28 at the intervening cater-corner positions. A catch element 30 is formed along one side of each housing component, and a corresponding notch 32 is formed into the opposite side. These several elements enable ready assembly of the two components 10, 10′, to provide a complete housing, by inserting the posts 26 of one component into the corresponding, confronting holes 28 of the other, for frictional engagement, and by causing the catch element 30 on one component to mechanically engage the corresponding notch 32 in the other.

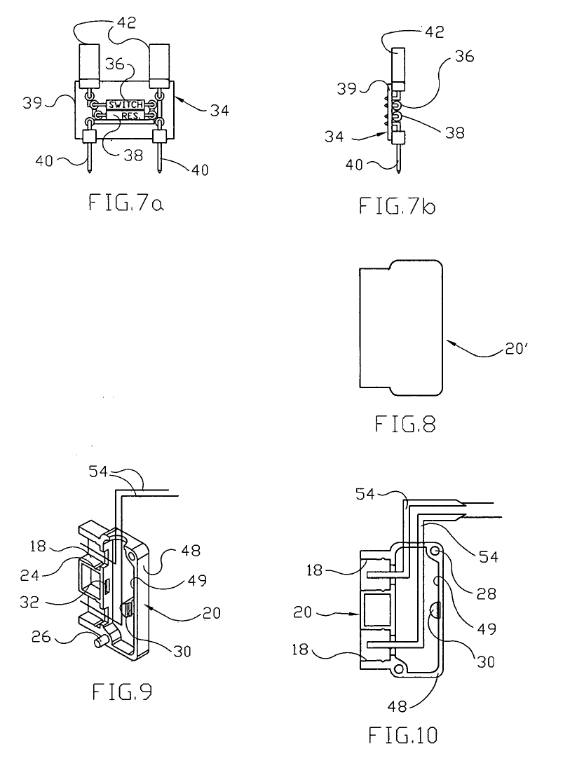

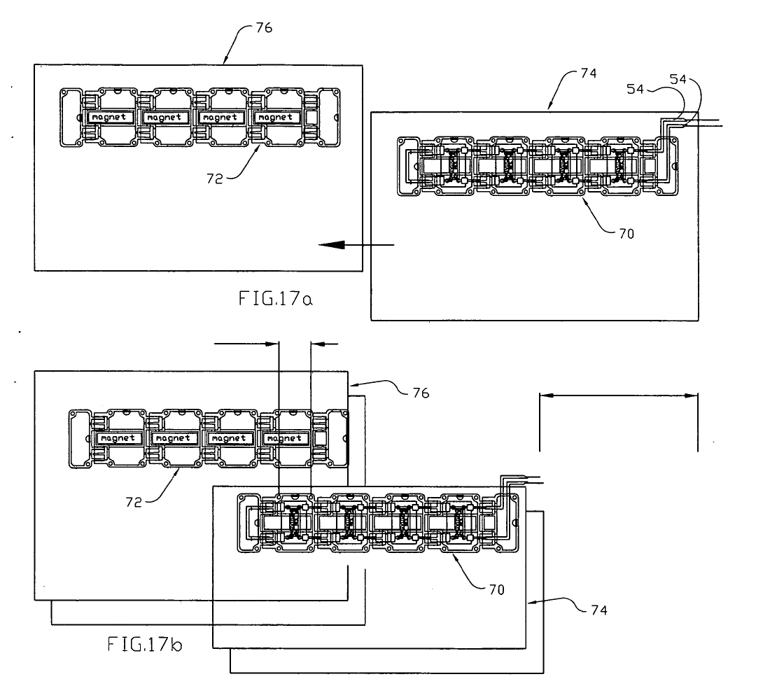

As depicted in FIGS. 2 and 4, the housing component 10 includes an electric circuit board, generally designated by the numeral 34. As best seen in FIGS. 7a and 7b, the circuit board 34 consists of a reed switch 36 and a common resistor 38, mounted upon a substrate 39 and electrically connected to a pair of conductive terminal pins or prongs 40 and a pair of conductive terminal sockets 42, placed at opposite ends of the substrate 39; the circuitry is shown diagrammatically in FIG. 16. The circuit board 34 is seated within the recess 14 of the housing component 10, with the terminal sockets 40 extending into the spaces defined within the male connector elements 16 and with the terminal sockets 42 contained within the channel sections 18 comprising the female connectors of the unit. Needles to say, when adjacent switch units are assembled the pins 40 plug into the sockets 42.

FIG. 6 depicts the housing component 10 fitted with a permanent magnet 44. Low wall structure 46 is molded into the recess 14 of the housing component for confining the magnet 44 and maintaining it in proper position.

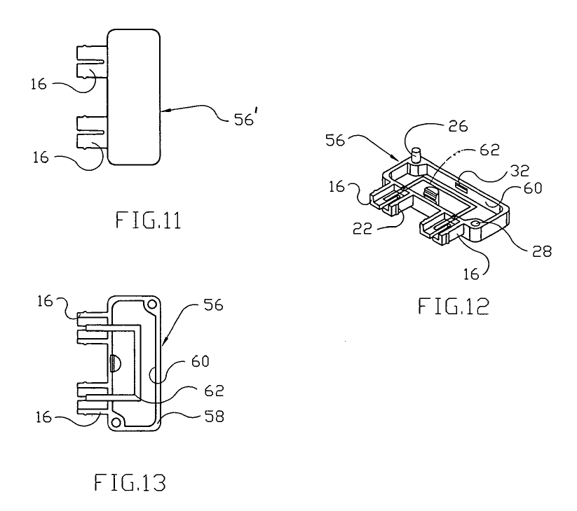

FIG. 8 provides a plan view of a female end cap utilized in the system of the invention and consisting of housing components that are identical to one another and are arbitrarily designated by the general numerals 20, 20′. As in the switch/resistor units and the magnet units depicted in FIGS. 1 through 6, the female end cap is constructed by assembling the housing components 20, 20′ in face-to-face relationship, utilizing pins 26, holes 28, catches 30 and notches 32. As seen in FIGS. 9 and 10, each housing component defines a body 48 with a recess 49, and also has structure defining a pair of parallel channel sections 18 which cooperatively form, in the assembled housing, parallel, inwardly-extending receptacles.

As best seen in FIG. 10, the female end cap receives a pair of wires 54, which provide conductive leads for electrical connection to a controller or the like (not shown). Suitable terminals (also not shown), such as the sockets 42 illustrated in FIG. 7, are electrically connected to the wires 54 and serve to engage the terminal pins 40 of an adjacent switch/resistor unit; these features are included in circuitry diagrammatically shown in FIG. 16.

FIG. 11 similarly provides a plan view of a male end cap utilized in the system of the invention, which also consists of a base housing component and a cover-housing component, generally designated respectively by the numerals 56 and 56′ (again, arbitrarily chosen). As in the case of the magnet and switch/resistor units, and the female end cap, the male end cap is constructed by assembling with one another the base housing component 56 and the cover housing component 56′, utilizing pins 26, holes 28, catches 30, and notches 32.

The housing components of the male end cap are formed with projecting male connector elements 16 which, in assembly, provide parallel projections for receipt in the receptacles that provide the female connecting elements of an adjacent module unit. In this instance, the housing component 56 contains a shunt wire 62 disposed in the recess 60 of the body portion 58, adapted to electrically engage suitable terminals (e.g., sockets 42) disposed within the channels of the adjacent switch/resistor unit; this feature is also depicted in the circuit diagram of FIG. 16. It will of course be appreciated that the end caps for the magnetic stack need include neither the wires 54 nor the wire 62.

As will be noted from FIG. 16, the conductor sections 64, 66, 68, provided on each circuit board 34 and connected to the terminals 40, 42, define a common circuit through the assembly of switch/resistor units employed in the system of the invention and connected by leads 54 to a controller. In the open position of the switches 36 depicted, the resistors 38 are connected in series in the assembly, cumulatively determining the current and voltage conducted through the stack and present at the leads 54. Closing of either or both of the switches 36, by magnetic actuation, short circuits (shorts out) the corresponding resistor 38 to thereby decrease the total resistance, measured at the wire leads 54, by a corresponding amount. A controller can then determine the number of switches that are closed, and in turn determine the mechanical position of any member on which either the switch stack or the magnet stack is mounted.

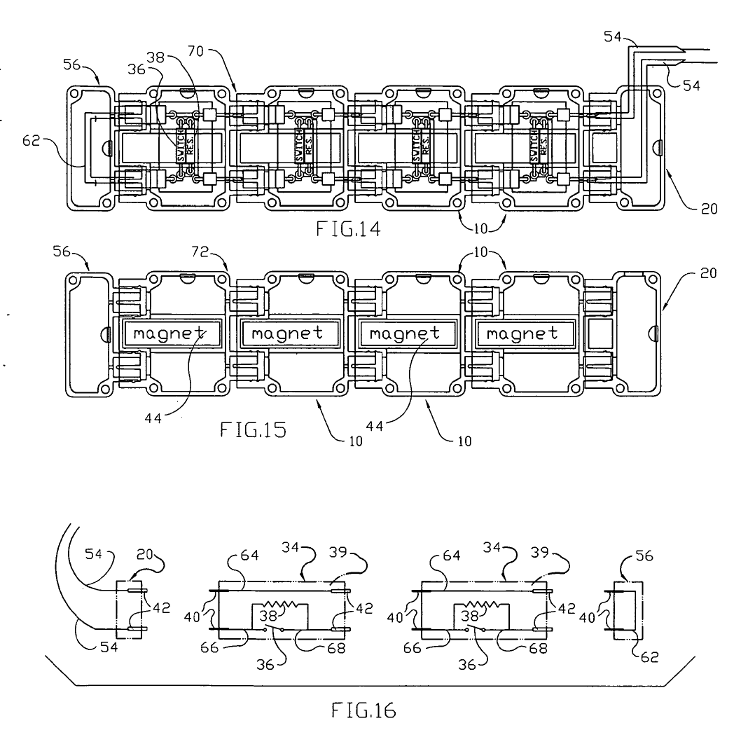

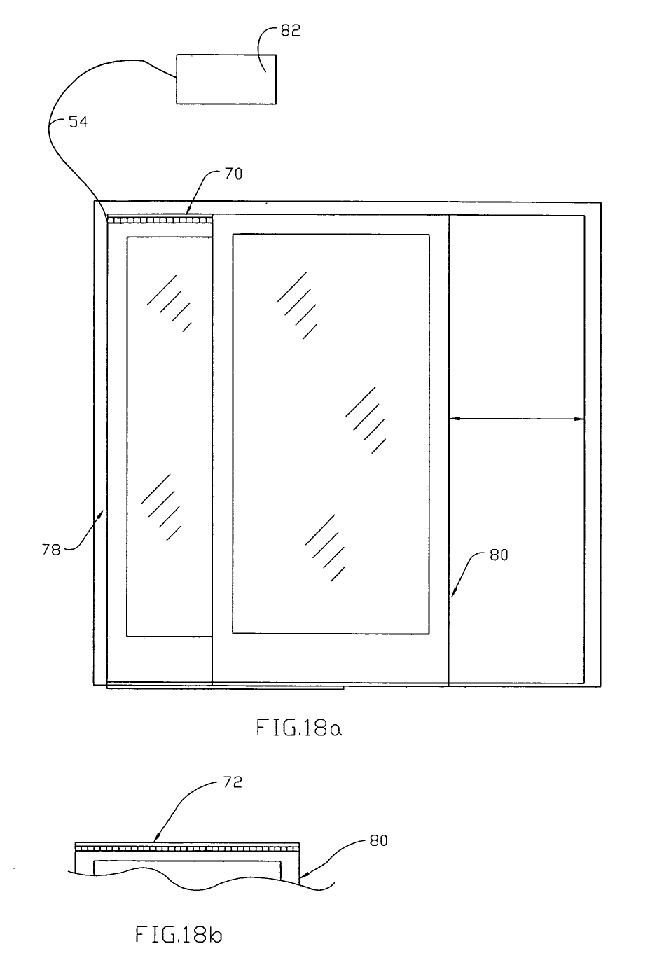

FIGS. 14 and 15 depict, respectively, a finished switch stack assembly and a finished magnet stack assembly comprising a system of the invention and generally designated, respectively by the numerals 70 and 72. FIGS. 17a and 17b show the two stack assemblies 70, 72 mounted upon two relatively movable, transversely proximate members 74 and 76. It will be appreciated that FIGS. 17a and 17b are isometric views, and that the member 70 is arranged to slide from the position shown in FIG. 18a to the position shown in FIG. 18b (and of course beyond), the members 70, 72 being disposed in sufficiently close proximity to one another that the magnetic fields produced by the magnets contained within the units of the magnet stack assembly 72 can pass into the units constituting the switch stack assembly 70, so as to effect actuation thereof. In the position depicted in FIG. 17b, one of the magnet units of the magnet stack 72 overlaps one of the units of the switch stack 70 (as indicated by the inwardly facing arrows), thus closing the switch 36 thereof, shorting out the associated resistor 38, reducing the total resistance of the circuit, and enabling a position calculation to be carried out; the double-headed arrow indicates the distance moved. Needless to say, if the member 74 were to move to a position of greater overlap with the member 72 (i.e., slide further to the left in FIG. 17b, as indicated by the arrow in FIG. 17a), two or more of the switches 36 would be opened and the calculations performed would indicate the increased travel distance.

A specific application for a system embodying the invention is depicted in FIGS. 18a and 18b, and involves the monitoring of sliding door travel relative to a fixed door. More particularly, a switch stack 70 is mounted (by use of a permanent, double-sided tape or by any other suitable means, such as glue, calk, mechanical fasteners or bands, interengaging mechanical structures, and the like) to extend along the top-molding piece of the fixed door 78, typically with a gap of ⅛ to 1¼ inch therebetween. A magnet stack 72 is similarly attached along the upper frame member of the sliding door 80. Depending upon the extent of overlap of the sliding door 80 relative to the fixed door 78, one or more of the normally open switches 36 in the stack 70 will be closed by the action of a corresponding number of magnets 44 in the stack 72, thereby decreasing the total resistance of the circuit and in turn enabling door position to be derived by an operatively connected control panel 82. The change of resistance can be used, for example, to calculate the length of the opening covered by the door or to determine the open doorway area. The switch and magnet stacks used in such an application would typically each consist of 36 units that are each one inch long, as assembled (i.e., not considering the length of the male projections), and including appropriate end caps, as described. The control panel 82 may take the form of a security panel, an HVAC control panel, a fire alarm panel, a data acquisition card, etc.

A similar arrangement can of course be utilized for determining the position of a double-hung window. Typically, the stacks of such a system would consist of 22 switch segments, each again having a one-inch effective length, and including suitable end caps.

Another representative application for systems embodying the invention is shown in FIG. 19, and enables determination of the level of a body of a liquid. For that purpose the switch stack 70 is mounted to extend along a vertical support member 84, and the magnet stack 72 is mounted to extend along the shaft 86 of a float assembly, slidably mounted on the member 84 using suitable guide elements 85 and including a pair of floats 88 attached to its lower end. Raising and lowering of the shaft 86, as effected by the floats 88, will produce a signal from which the control panel can derive the level of the liquid. The controller in such an installation could function to effect opening or closing of valves for adding or removing liquid from a tank, or to initiate other actions.

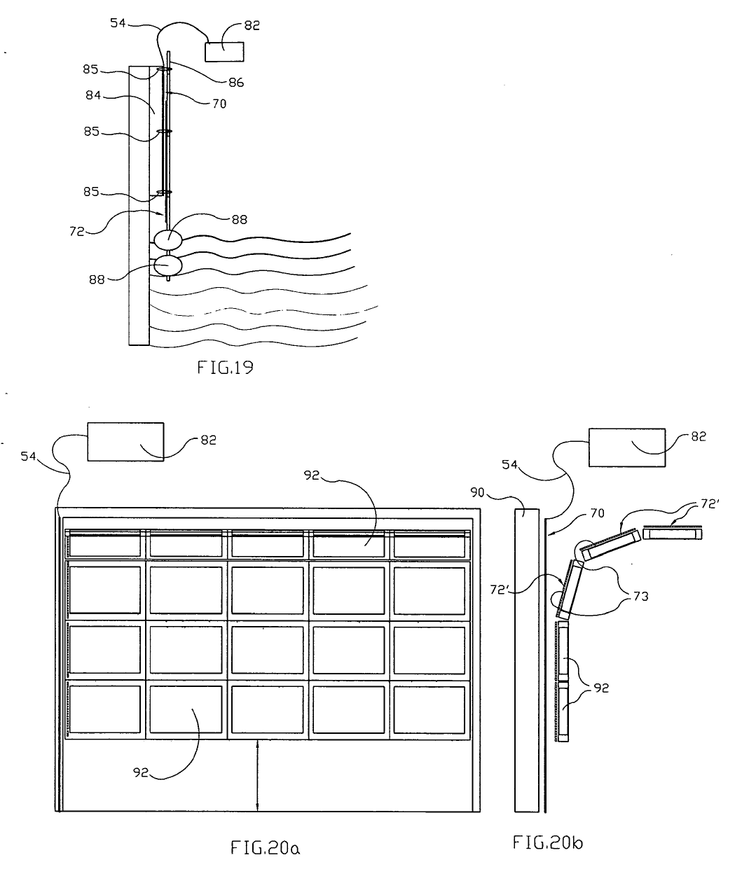

FIGS. 20a and 20b illustrate an application in which a system of the invention is employed for determining garage door height position. In this instance the switch stack 70 would typically be adhesively mounted upon a stationary frame member 90, with a number of relatively short magnet stacks 72′ being adhesively mounted upon the several panels 92 constituting the overhead door (the adhesive element 73 is visible only in FIG. 20b). While, as can be seen, each of the door panels 92 would normally carry a magnet stack 72′, the several short stacks need not be joined to one another to produce a single assembly. For this application the arrays of switch and magnet units would typically be dimensioned and arrange for monitoring 96 inches of door travel, and it indicates a reason why the switch stack (with its integral circuitry) may preferably (but not necessarily) be mounted upon a stationary member.

FIGS. 21a and 21b depict components of systems embodying the invention in which the active units (e.g., switch and magnet units) of the arrays are not attached directly to one another but include instead an interposed connector 98, comprised of assembled housing components 99. As shown in these figures, the unit 100 and its housing component 102 are formed with female connecting structures 104 on both ends, and the connector 98 is formed with male elements 106 on both of its opposite ends; a number of active units would be joined by interposed connectors to form a complete array, as indicated in FIG. 21a.

Rather than having the male elements on the connectors and the female structures on the active units, it is obvious not only that those features can be reversed but also that other combinations, and different forms of connecting elements, can be employed. It is also obvious that when the active units are magnet units the connectors employed would normally be fully insulating and devoid of any electrically conductive means. As suggested in FIG. 21c, however, connectors for switch units would include conductive elements (as indicated by wires 108 fragmentarily shown in broken line, but having such other conventional features that may be necessary) to electrically interconnect the circuit sections of the two proximate switch units.

The circuit board depicted in FIG. 22, generally designated 34′, represents an alternative switch arrangement, in which the element 38′, marked “COIL,” provides the resistive element and the element 36,′ marked “CONNECTING,” comprises the switch; e.g., an inductance coil can be stacked and actuated by a magnet. Various means for providing effective resistance in the circuit, and for effectively connecting and disconnecting the resistance, in accordance with the present invention, will be evident to those skilled in the art.

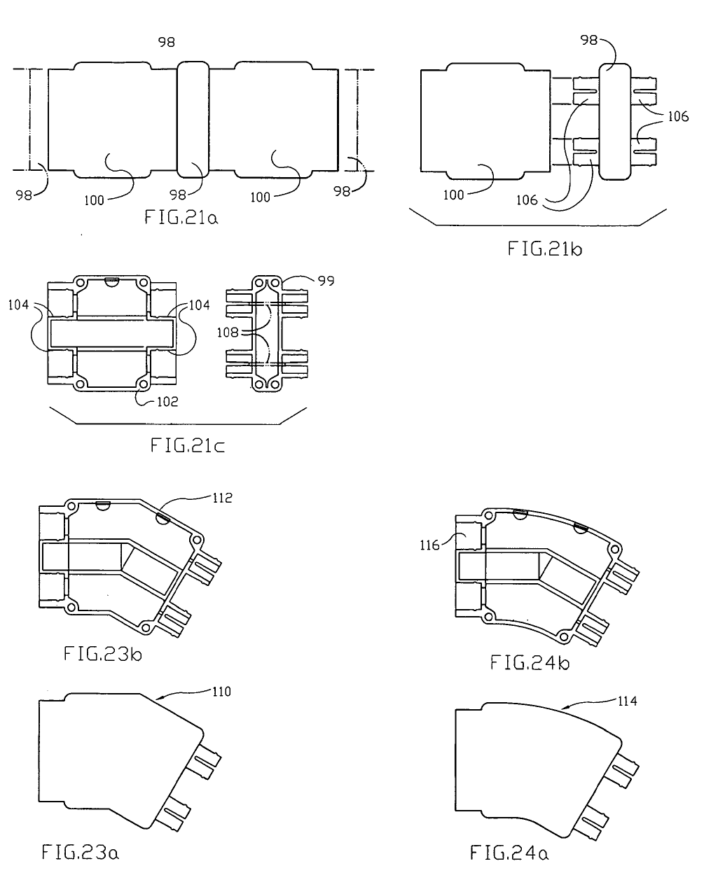

Except for the angular shape, the unit of FIG. 23a, generally designated by the numeral 110, and the housing component 112 of FIG. 23b of which the unit is constructed, are entirely equivalent to the corresponding components hereinabove described. As will be self evident, an array of the units 110 would have a multisided polygonal form, and would be of such extent as to provide either a continuous, closed assembly (normally requiring no end caps to interconnect free terminals) or an assembly in which opposite end units are mutually spaced.

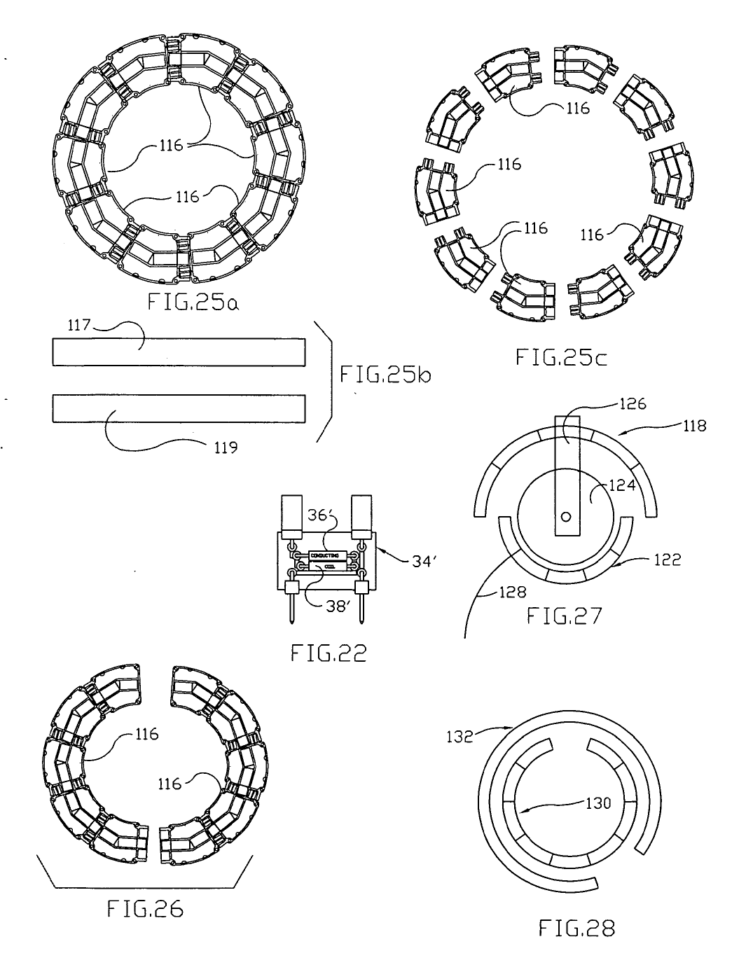

FIGS. 24a and 24b depict a unit, generally designated by the numeral 114, and a housing component 116 that are similar to those of FIG. 23 except for being arcuate rather than of angular form. As will be appreciated from FIGS. 25a and 25c, assembly of the units 114 will produce generally circular arrays, which may (if of the same diameter) be employed in a side-by-side or vertically overlying relationship to one another, as shown in FIG. 25b, with one of the rectangles 117 indicating the sensor array and the other 119 indicating the actuator array; here again, end caps would not normally be required.

Alternatively, an array of such units may be of sectorial (e.g., semicircular) form, as shown in FIG. 26, wherein one of the semicircular arrays would comprise the switch/resistor (sensor) component, and the other semicircular array would comprise the magnet (actuator) component. Needless to say, suitable electrical circuitry and electrical connections, and arrangements of switches and magnets within the arrays of FIGS. 25 and 26, would be employed to provide systems that are operative for their intended purposes.

An application for curvilinear arrays of switch and magnet units is schematically illustrated in FIG. 27, wherein the magnet array, generally designated by the numeral 118, is mounted on the body (not shown) of a valve, and the switch array, generally designated by the numeral 122, is mounted on the operating shaft 124, to which a handle 126 is attached; a sensor lead is shown at 128. Angular movement of the shaft 124 relative to the body can be measured using the system of the invention so as to determine the degree to which the valve is open.

Finally, FIG. 28 illustrates that the sectorial extent of curvilinear arrays or components may vary greatly. As depicted, both components, generally designated respectively by the numerals 130 and 132, extend through an arc of about 315 degrees. As a practical matter, the arcs may be as narrow as perhaps 45 degrees or less, but that of course depends, at least to some extent, upon the circumferential length of any given component. The figure also indicates that the actuator 132 may comprise a single piece (e.g., a continuous strip of magnetic material) rather than being an array of separate units.

As indicated above, many variations may be made in the system of the invention, as described herein, without departure from its underlying concepts. For example, while permanent magnets will usually be preferred for use in a magnet actuator stack, it is possible that electromagnets may be employed instead. Indeed, the actuation system may for example employ optical rather than magnetic, principles (or effects in other regions of the electromagnetic radiation spectrum), assuming of course that the sensor is responsive to the actuating energy. Also, while the provision of a single form of housing, assembled from a pair of identical components, offers obvious manufacturing and installation advantages, that need not necessarily be the case.

As is also indicated above, while the embodiments of the invention most fully described employ an array of actuating units, the invention may more broadly be implemented by using a continuous form of actuating means, such as a strip of magnetic tape applied to a substrate, or an elongate form of a radiation-emitting component. Such a continuous element might only need to be cut to proper length, and applied utilizing its adhesive backing.

Finally, while all sensor units will usually employ resistance elements having the same value, the resistances may vary. For example, the resistance may increase proportionately to the length of the array (e.g., doubling every inch), or the increases could be in a logarithmic relationship (e.g., 1, 10, 100, 1000 . . . ).

1-31. (canceled)

32. A position-sensing system capable of indicating the relative position of two objects, said system comprising:
a first array including a plurality of first modular units; each of said first modular units being capable of mechanically connecting to adjacent first modular units, whereby said first modular units being arranged seriatim to define said first array; each of said first modular units including means operable to create a magnetic field;
a second array including a plurality of second modular units, and a third modular unit;
each of said second modular units comprising input and output electrical connections, and electrical components including an switch component having two operating states, said switch component being responsive to a magnetic field for changing its operating state; said second modular unit exhibiting relatively high electrical resistance for one operating state and relatively low electrical resistance for the other operating state;
each of said second modular units being capable of mechanically and electrically connecting to adjacent second modular units, and said third modular unit being capable of mechanically and electrically connecting to one of said second modular units; whereby said second modular units and said third modular unit being arranged seriatim to define said second array with said third modular unit being positioned at one of the ends of said second array, and said second modular units and said third modular unit forming a continuous electrical circuit with the input to said electrical circuit being the input electrical connections for said second modular unit positioned at the opposite end from said third modular unit;
said first array being operable for being associated with a first object and said second array being operable to a second object; said first and second arrays being in a generally confronting relationship; whereby the magnetic field produced by at least some of the first modular units effects the state of at least some of second modular units, and the relative shift of position between said first and second arrays results in a change of state of at least some of the second modular units; thereby changing the electrical resistance of said second array, whereby the change in electrical resistance is related to the relative shift of position of said first and said second object.

33. The system as claimed in claim 31, wherein said modular units each comprises a housing fabricated from electrically insulating material.

34. The system as claimed in claim 31, wherein said first modular units are interlocked mechanically and capable of being separated.

35. The system as claimed in claim 31, wherein said second modular units are interlocked mechanically and capable of being separated.

36. The system as claimed in claim 31, wherein said first modular units cannot be mechanically connected to said second modular units in the same manner as said first modular units are mechanically connected to each other.

37. The system as claimed in claim 31, wherein said third modular unit cannot be mechanically connected to said first modular units in the same manner as said third modular unit can be connected to said second modular unit.
